(19) United States
(12) Patent Application Publication
(10) Pub. No.: US 2025/0368499 A1
(43) Pub. Date: Dec. 4, 2025

(54) MICROELECTROMECHANICAL SYSTEMS (MEMS) TRANSDUCER OVERSTRESS PROTECTION

(71) Applicant: QUALCOMM Incorporated, San Diego, CA (US)

(72) Inventors: Jeroen BIELEN, Mook (NL); Robert John LITTRELL, Belmont, MA (US); Kun GAO, Helmond (NL); Hamid BASAERI, Medford, MA (US)

(21) Appl. No.: 18/678,905

(22) Filed: May 30, 2024

(51) Int. Cl. B81B 3/00; H04R 7/04; H04R 17/02; H04R 19/04; H04R 31/00

(52) U.S. Cl. CPC B81B 3/0051; H04R 7/04; H04R 17/02; H04R 19/04; H04R 31/006; B81B 2201/0257; H04R 2201/003

(57) ABSTRACT

Aspects of the disclosure relate to microelectromechanical systems (MEMS) and A device implementation may include a substrate having a top surface, a bottom surface opposite the top surface, a bottom surface aperture, and a top surface aperture, an acoustic cavity comprising a volume extending from the bottom surface aperture to the top surface aperture, an electroacoustic structure formed at the top surface of the substrate, where the electroacoustic structure comprises an acoustic layer, and where the acoustic layer has a functional range of motion, and a mechanical overstress protection structure formed over the acoustic layer and positioned to contact the acoustic layer when the acoustic layer approaches or exceeds an end of the functional range of motion deflecting away from the substrate.

### TECHNICAL FIELD

This disclosure relates generally to acoustic transducers, and more specifically to microelectromechanical systems (MEMS) vibration sensing devices with overstress protection.

### BACKGROUND

A micro-electro-mechanical system (MEMS) acoustic transducer/sensor converts acoustic energy into electrical signal, and/or converts an electrical signal into acoustic energy. An example of a MEMS acoustic transducer is a MEMS microphone, which converts sound pressure into an electrical voltage. Based on their transduction mechanisms, MEMS microphones can be made in various forms, such as capacitive microphones or piezoelectric microphones.

MEMS capacitive microphones and electric condenser microphones (ECMs) currently dominate the consumer electronics market for microphones. Piezoelectric MEMS microphones, however, occupy a growing portion of the consumer market, and have unique advantages compared to their capacitive counterparts. Among other things, piezoelectric MEMS microphones do not require a back plate, eliminating the squeeze film damping, which is an intrinsic noise source for capacitive MEMS microphones. In addition, piezoelectric MEMS microphones are reflow-compatible and can be mounted to a printed circuit board (PCB) using typical lead-free solder processing, which could irreparably damage typical ECMs.

A MEMS transducer, such as a microphone, may be damaged by a mass of high velocity air impacting the microphone's diaphragm. For example, some mobile phones include a MEMS microphone disposed at an opening in the phone's surface. If the mobile phone falls and lands such that the opening hits a flat surface, a mass of air may be forced into the opening and impact the diaphragm. Similarly, if pressurized air (e.g., an air gun) is used for cleaning a device, a similar mass of air may be forced into a MEMS transducer opening. In response, the diaphragm may move beyond its physical limits and deform or break, or may impact another structure, such as a the backplate in a capacitive microphone.

Conventional capacitive microphones have a flexible diaphragm next to a backplate. Depending on the location of the diaphragm and backplate, an oncoming mass of air may reach the diaphragm first and push the diaphragm into the backplate, potentially damaging the diaphragm and/or causing the diaphragm to stick to the backplate. Alternately, if the mass of air reaches the backplate first, it may pass through the backplate and push the diaphragm away from the backplate, potentially damaging the diaphragm.

Some mobile phone manufacturers require MEMS microphones to withstand a fall from a specified height, such as one meter, onto a flat surface without detrimental effect on the MEMS microphone.

Manufacturers of MEMS microphones have taken a variety of approaches to make their microphones more robust. Some manufacturers have made their diaphragms and their suspension components thicker and/or stiffer, but such diaphragms are less flexible and their response to impinging acoustic energy is undesirably limited relative to more flexible diaphragms.

### SUMMARY

Aspects of the present disclosure describe microelectromechanical system (MEMS) devices, systems, methods associated with MEMS microphones having overstress protection.

In some aspects, the techniques described herein relate to a microelectromechanical system (MEMS) transducer, including: a substrate having a top surface, a bottom surface opposite the top surface, a bottom surface aperture, and a top surface aperture; an acoustic cavity including a volume extending from the bottom surface aperture to the top surface aperture; an electroacoustic structure formed at the top surface of the substrate, wherein the electroacoustic structure includes an acoustic layer, and wherein the acoustic layer has a functional range of motion; and a mechanical overstress protection structure formed over the acoustic layer and positioned to contact the acoustic layer when the acoustic layer approaches or exceeds an end of the functional range of motion deflecting away from the substrate.

In some aspects, the techniques described herein relate to a MEMS transducer, wherein the electroacoustic structure includes a capacitive MEMS microphone, and wherein the acoustic layer includes an acoustic membrane of the capacitive MEMS microphone.

In some aspects, the techniques described herein relate to a MEMS transducer, wherein the electroacoustic structure includes a piezoelectric MEMS microphone, and wherein the acoustic layer includes a plurality of cantilevered piezoelectric beams.

In some aspects, the techniques described herein relate to a MEMS transducer, further including a kinetic energy diverter formed in the acoustic cavity.

In some aspects, the techniques described herein relate to a MEMS transducer, wherein the electroacoustic structure is coupled to the substrate in an first area surrounding the top surface aperture; and wherein the mechanical overstress protection structure is coupled to the substrate in a second area surrounding the first area.

In some aspects, the techniques described herein relate to a MEMS transducer, wherein the mechanical overstress protection structure is a flat stopper positioned with a gap distance above a neutral position of the electroacoustic structure.

In some aspects, the techniques described herein relate to a MEMS transducer, wherein the gap distance is approximately constant and between 3 and 25 micrometers (um).

In some aspects, the techniques described herein relate to a MEMS transducer, wherein the mechanical overstress protection structure is fabricated from a material selected from aluminum nitride (AlN), aluminum scandium nitride (AlScN), molybdinum (Mo), silicon nitride (SiN), silicon oxide (SiO2), amorphous silicon (a-Si), polycrystalline silicon, copper (Cu), or nickel (Ni).

In some aspects, the techniques described herein relate to a MEMS transducer, wherein the mechanical overstress protection structure is fabricated with a multi-layer structure including two or more different materials.

In some aspects, the techniques described herein relate to a MEMS transducer, wherein the mechanical overstress protection structure includes a plurality of cantilevered stoppers extending over the top surface aperture.

In some aspects, the techniques described herein relate to a MEMS transducer, wherein each cantilevered stopper includes a linearly tapered stopper positioned over a corresponding gap between MEMS beams of the electroacoustic structure.

In some aspects, the techniques described herein relate to a MEMS transducer, wherein each cantilevered stopper includes a non-linearly tapered stopper extending from the second area to a central area above the top surface aperture.

In some aspects, the techniques described herein relate to a MEMS transducer, wherein a first gap distance between the electroacoustic structure and the mechanical overstress protection structure is between approximately 0 micrometers (um) and 5 um above the first area, and wherein a second gap distance above the central area of the top surface aperture.

In some aspects, the techniques described herein relate to a MEMS transducer, wherein the mechanical overstress protection structure includes a clamped structure configured as a circular membrane, a polygon, or a web.

In some aspects, the techniques described herein relate to a MEMS transducer, wherein the mechanical overstress protection structure includes the web with a plurality of beams, wherein each beam is positioned with an opposite beam across the top surface aperture, and wherein the mechanical overstress protection structure further includes a plurality of radial structures positioned at different distances from an open central area.

In some aspects, the techniques described herein relate to a MEMS transducer, wherein the plurality of radial structures include curved spring structures.

In some aspects, the techniques described herein relate to a MEMS transducer, further including a plurality of support beams coupled between the plurality of radial structures at different angles.

In some aspects, the techniques described herein relate to a MEMS transducer, wherein the plurality of beams are curved using a stress gradient in a deposition process to configure a changing gap distance from the first area to the open central area.

In some aspects, the techniques described herein relate to a piezoelectric microelectromechanical system (MEMS) device, including: a substrate having a top surface, a bottom surface opposite the top surface, a bottom surface aperture, and a top surface aperture; an acoustic cavity including a volume extending from the bottom surface aperture to the top surface aperture; a plurality of cantilevered piezoelectric beams coupled to the substrate in a perimeter area around the acoustic cavity and extending into or over the acoustic cavity; a mechanical overstress protection structure formed over the plurality of piezoelectric beams and coupled to the substrate in a second area surrounding the perimeter area, wherein the mechanical overstress protection structure is positioned to contact one or more of the plurality of cantilevered piezoelectric beams as they approach or exceed an upper end of a functional range of motion.

In some aspects, the techniques described herein relate to a method of fabricating a microelectromechanical system (MEMS) transducer, including: forming a substrate having a top surface and a bottom surface opposite the top surface; forming an acoustic cavity in the substrate to create a top surface aperture and a bottom surface aperture, wherein the acoustic cavity includes a volume extending from the bottom surface aperture to the top surface aperture; forming electroacoustic structure including an acoustic layer at the top surface of the substrate, wherein the acoustic layer has a functional range of motion; and forming a mechanical overstress protection structure positioned over the acoustic layer to contact the acoustic layer when the acoustic layer approaches or exceeds an end of the functional range of motion deflecting away from the substrate. The foregoing, together with other features and embodiments, will become more apparent upon referring to the following specification, claims, and accompanying drawings.

### BRIEF DESCRIPTION OF DRAWINGS

FIG. 1A illustrates an example of a microelectromechanical system (MEMS) acoustic transducer with overstress protection in accordance with aspects described herein.

FIG. 1B illustrates an example of a MEMS acoustic transducer with overstress protection in accordance with aspects described herein.

FIG. 1C illustrates aspects of a MEMS sensor system in accordance with aspects described herein.

FIG. 1D illustrates aspects of a MEMS sensor device in accordance with aspects described herein.

FIG. 1E illustrates aspects of a pressure pulse that can overstress a MEMS acoustic transducer in accordance with aspects described herein.

FIG. 2 illustrates a plan view of a piezoelectric MEMS transducer that may be used in accordance with aspects described herein.

FIG. 3 illustrates a cross-sectional view of one portion of a piezoelectric MEMS beam that can be used in accordance with aspects described herein.

FIG. 4A illustrates aspects of a piezoelectric MEMS transducer in accordance with aspects described herein.

FIG. 4B illustrates aspects of a piezoelectric MEMS transducer with overstress protection in accordance with aspects described herein.

FIG. 5A illustrates aspects of an example overstress protection structure positioned relative to a MEMS electroacoustic structure in a neutral position in accordance with aspects described herein.

FIG. 5B illustrates aspects of an example overstress protection structure positioned relative to a MEMS electroacoustic structure in a neutral position in accordance with aspects described herein.

FIG. 5C illustrates aspects of an example overstress protection structure positioned relative to a MEMS electroacoustic structure in a neutral position in accordance with aspects described herein.

FIGS. 6A-H illustrate top views of overstress protection structures in accordance with aspects described herein.

FIG. 7 illustrates a top view of clamped overstress protection structures in accordance with aspects described herein.

FIGS. 8A-D illustrate top views of cantilevered stoppers implemented as overstress protection structures in accordance with aspects described herein.

FIGS. 9A-D illustrate aspects of cantilevered beams implemented as overstress protection structures in accordance with aspects described herein.

FIG. 10 illustrates a method associated with overstress protection of MEMS transducers in accordance with aspects described herein.

FIG. 11 illustrates a MEMS transducer with overstress protection and kinetic energy diversion in accordance with aspects described herein.

FIG. 12 is a block diagram of a computing device that can be used with implementations of a MEMS transducer with overstress protection in accordance with aspects described herein.

Like reference symbols in the various drawings indicate like elements.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

Aspects described herein include microelectromechanical systems (MEMS) acoustic transducers with overstress protection. Such transducers convert motion energy (e.g., air vibrations) into electrical signals. The size and low power associated with such MEMS transducers can allow the MEMS transducers to be used in environments where other such sensors are unavailable. Such size and sensitivity, however, render MEMS acoustic transducers vulnerable to overstress from damage or significant air impulses that can occur, for example from a device being dropped or an impact against an acoustic port of a device including a MEMS transducer.

The vulnerability of such MEMS acoustic transducers can result from membranes or beams that are directly involved in conversion of motion energy to electrical signals. Overstress air pulses can cause deformation of the membranes or beams beyond a functional range of motion, resulting in damage to the membranes or beams of the acoustic transducer. Aspects described herein include physical overstress protection structures that use physical contact to prevent deformation of MEMS beams or membranes to a point of breaking. Such structures can include various beam membrane, or web structures positioned on the opposite side of an electroacoustic structure from an acoustic port. When an air impulse enters the acoustic port and the electroacoustic structure deflects away from the port, contact with the overstress protection structure can reduce the probability of damage to a MEMS transducer. Such an overstress protection structure can be designed with various trade-offs for cost, manufacturability, level of protection, and impact on MEMS transducer performance.

Details of various illustrative aspects are discussed further below.

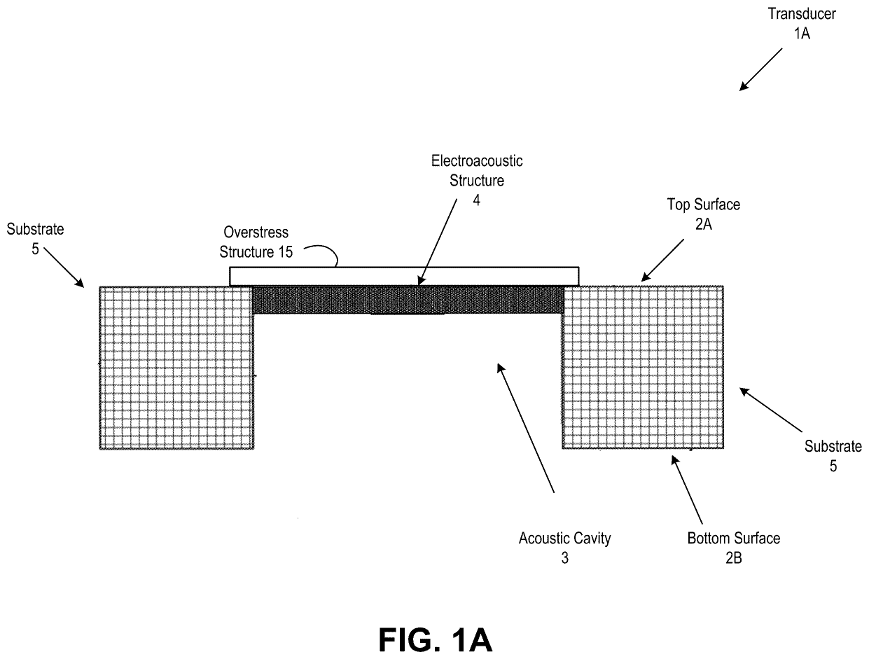

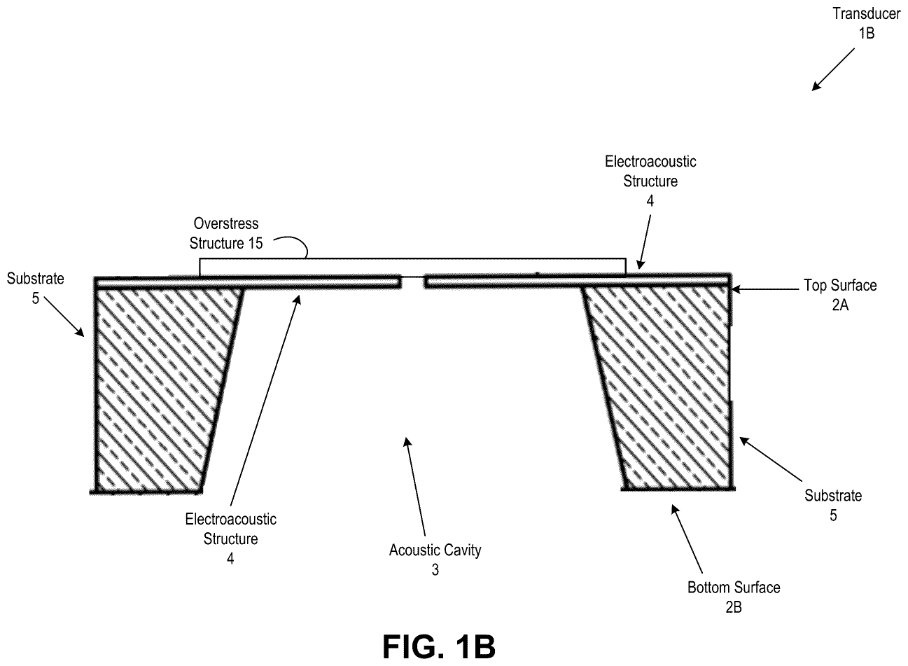

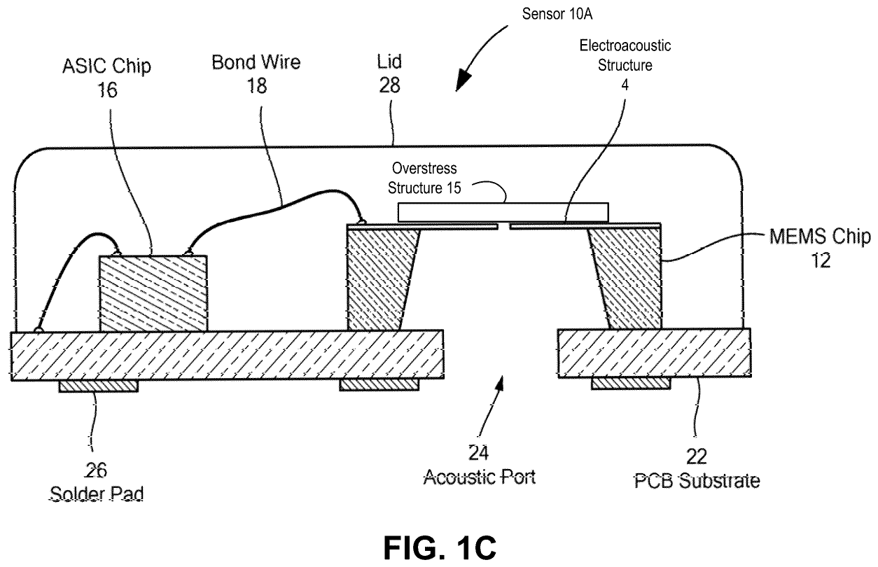

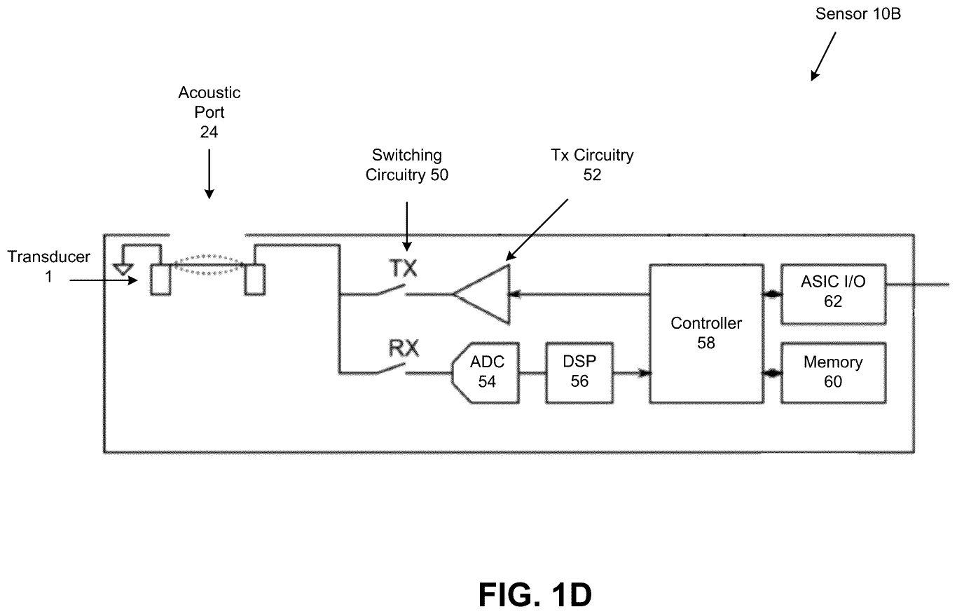

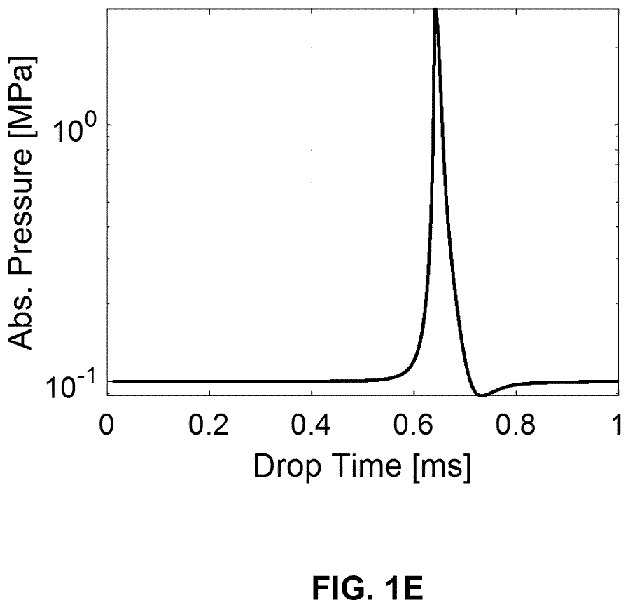

FIG. 1A illustrates an acoustic MEMS transducer 1A including an overstress structure 15 for overstress protection in accordance with aspects described herein. The acoustic MEMS transducer 1A includes a substrate 5 (e.g., a semiconductor substrate such as silicon (Si)) having a top surface 2A and a bottom surface 2B. An acoustic cavity is formed through the substrate 5, with the acoustic cavity bounded by an aperture in the top surface 20 and an aperture in the bottom surface 2B. An electroacoustic structure 4 is formed at or above the top surface 2A and at or above the top surface 2A aperture. The electroacoustic structure 4 includes an acoustic layer (e.g., a membrane) in order to receive vibrations passing through the acoustic cavity 3, and to transduce the vibrations (e.g., sound) into an electrical signal via the electroacoustic structure 4. As detailed further below, in some situations, the vibrations passing through the acoustic cavity 3 can include pressures significantly outside normal operating conditions. Such pressures can occur, for example, due to a drop or an impact on an acoustic port connected to the acoustic cavity 3. Such pressures can force or move the electroacoustic structure 4 upwards past a functional operating position, resulting in damage (e.g., breaking of the acoustic layer and/or other elements of the electroacoustic structure 4) through excessive deformation of the electroacoustic structure 4 or separation of the electroacoustic structure 4 from the substrate 5. The overstress structure 15, in accordance with aspects described herein, can physically contact the electroacoustic structure 4 to prevent or reduce the likelihood of such damage.

The diagram of FIG. 1A illustrates a high level diagram of the transducer 1A, where the electroacoustic structure 4 has a top surface aligned with the top surface 2A of the substrate 5. A contact between the electroacoustic structure 4 and the substrate 5 occurs in an area at or inside the boundary of the acoustic cavity with the top surface 2A of the substrate. The overstress structure 15 is supported by a second area of the top surface 2A surrounding the top surface 2A aperture of the acoustic cavity and the contact area between the electroacoustic structure and the substrate 5. Such a structure is associated with capacitive MEMS microphones, where the electrode structure 4 is implemented as a MEMS membrane with supporting electrical circuitry and connections to generate an electrical signal from vibrations passing through the acoustic cavity. Overstress structure 15 can provide a physical support to such a MEMS membrane of a capacitive MEMS microphone in accordance with aspects described herein, in addition to configurations with other electroacoustic structures (e.g., piezoelectric MEMS devices as well as capacitive MEMS devices).

FIG. 1B illustrates an example of a MEMS acoustic transducer 1B including the overstress structure 15 for overstress protection in accordance with aspects described herein. The transducer 1B illustrates an implementation of a piezoelectric MEMS transducer, with the electroacoustic structure 4 including a piezoelectric layer formed over the top surface 2A of the substrate. Just as described above, the electroacoustic structure 4 converts vibrations passing through the acoustic cavity 3 (e.g., via an aperture in the bottom surface 2B and an aperture in the top surface 2A of the substrate 5) into electrical signals. As also described above, high pressure impulses (e.g., as illustrated by FIG. 1E), can force the electroacoustic structure beyond a functional range of motion, causing damage through excessive deformation or breakage of the electroacoustic structure 4. Additional details of various implementations of the overstress structure 15 are detailed below.

FIG. 1C illustrates aspects of a MEMS sensor 10A system in accordance with aspects described herein. The MEMS sensor 10A includes a transducer having the electroacoustic structure 4 protected by the overstress structure 15 as detailed above. Additionally, the sensor 10A is shown as including a lid 28, an application specific integrated circuit (ASIC) chip 16, and a printed circuit board (PCB) substrate 22. As shown by FIG. 1C, transducers such as the transducer 1B can be implemented on a MEMS chip 12 formed using a substrate such as the substrate 5. In some aspects, the MEMS chip 12 can include multiple transducers or other devices (not shown) in addition to the acoustic MEMS transducer. The sensor 10A includes an acoustic port 24 formed in the PCB substrate 22, and the PCB substrate 22 supports the MEMS chip 12 and the ASIC chip 16. The acoustic port 24 leads to a bottom aperture of the acoustic cavity 3 in the substrate 5 of the MEMS chip 12. In other implementations, other such configurations of the acoustic port 24 can be used so long as a path for acoustic pressure to reach the electroacoustic structures 4 is present.

FIG. 1C illustrates the ASIC chip 16 and the MEMS chip 12 connected by a bond wire 18. In some aspects, rather than implement the system with two separate chips, some embodiments may implement both the MEMS chip 12 and the ASIC chip 16 as part of the same die. Accordingly, discussion of separate chips is for illustrative purposes. In addition, in other embodiments the ASIC 16 may be implemented on a die in a separate package with one or more interconnects electrically coupling the MEMS chip 12 to the ASIC 16.

FIG. 1D illustrates aspects of a piezoelectric microelectromechanical system (MEMS) sensor 10B in accordance with aspects described herein. As illustrated, the sensor 10B includes a piezoelectric MEMS transducer 1. The piezoelectric MEMS transducer 1 can be implemented on a MEMS chip such as the MEMS chip 12 of FIG. 1A. An output of the transducer 1 is coupled to an analog-to-digital converter (ADC) 54, which accepts an analog signal from the output of the transducer 1 and converts the analog signal (e.g., which is a transduced signal from motion vibrations detected at the transducer 1) to a digital signal. An output of the ADC 54 is provided to a digital signal processor (DSP) 56, which can perform preprocessing, digital filtering, or other signal conditioning on the information from the transducer 1, and provide an output signal to a controller 58. The controller 58 can further process the information from the transducer 1 to generate a digital data signal corresponding to the analog signal output from the transducer 1. The digital data signal can be stored in a memory 60 on the sensor 10B, or can be output to a data path via application specific integrated circuit (ASIC) input/output (I/O) circuitry 62.

FIG. 1D further illustrates inclusion of the acoustic port 24. Similar to the description above, the sensor 10B can allow acoustic waves to be transmitted out from the transducer 1 in a transmit mode, or to be sensed in a receive mode. Switching circuitry 50 allows controller 58 to select between receive (Rx) and transmit (Tx) operation. In a Tx mode, an electrical signal associated with an acoustic wave to be generated by the transducer 1 is received as an input at the ASIC input/output (I/O) 62, and passed to controller 58. The signal (e.g., as modified by the controller 58 to shape this signal for the transducer 6) may be stored in memory 60 for later use, or passed to Tx circuitry 52 for transmission. The Tx circuitry 52, as part of transmission operations, can perform additional waveform conditioning and amplification (e.g., via a power amplifier), before being sent to the transducer 6 to be converted to acoustic signals. In some aspects, the Tx circuitry 52 may be optional.

In a receive mode, the MEMS chip 12 receives incident acoustic waves via the acoustic port 24, which are converted to electrical signals by the transducer 1. The ADC 54 and the DSP 56 convert the analog electrical signal from the MEMS chip 12 to a format acceptable to the controller 58, which can either store the signal in memory 60 or transmit the signal to additional processing circuitry of a larger device via the ASIC I/O 62.

In some aspects, multiple separate sensor packages having MEMS acoustic transducers with overstress protection can be included in a single device. In other aspects, a shared package can be used for multiple transducers (e.g., on a shared PCB substrate such as the PCB substrate 22 with the same lid such as the lid 28).

FIG. 1E illustrates aspects of a pressure pulse that can overstress a MEMS acoustic transducer in accordance with aspects described herein. As indicated above, when a transducer 1, 1A, or 1B or a sensor 10A or 10B is dropped or an impact occurs at the acoustic port 24, a large pressure pulse can pass through the acoustic cavity 3 of an associated transducer and impact the electroacoustic structure 4 of a transducer. FIG. 1E illustrates an example of such a pulse. Normal operating pressures of a MEMS transducer (e.g., pressures due to a voice or other audio) are typically in the order of millipascals (mPa) to pascals (Pa), and will not exceed the millibar level. Such pressures are significantly less than the pressure that can occur from a drop or air gun cleaning which can be above 1 bar to 50 bar (e.g., several megapascals) or higher. Similarly, acceleration loads are typically in the range of a millionth of standard gravity (uG) units to single digit standard gravity units (G), while overstress loads can reach thousands of standard gravity units (kG) or higher.

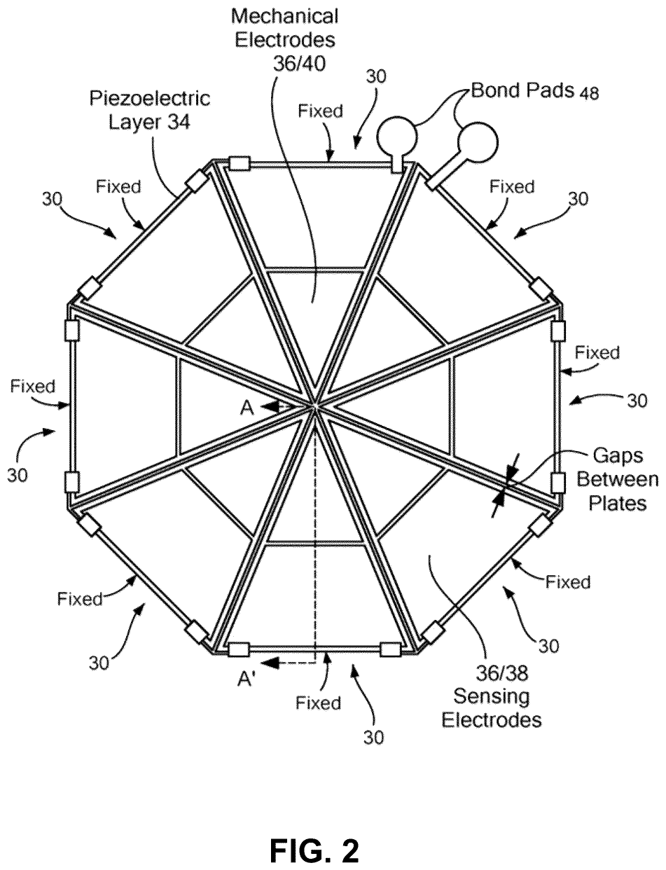

FIG. 2 illustrates a plan view of a piezoelectric MEMS transducer that may be used in accordance with aspects described herein. FIG. 2 schematically shows a plan view of a piezoelectric MEMS acoustic transducer of a MEMS chip (e.g., the MEMS chip 12) that can be implemented with an overstress structure 15 in accordance with aspects described herein. The transducer of FIG. 2 is implemented using eight MEMS cantilevers (e.g., also known as “sense arms”, “sense members”, “beams”, or “cantilevered beams” as part of one or more acoustic layers of a device) formed as piezoelectric triangular cantilevers 30. These members together form an octagonal MEMS transducer that can be used to implement a microphone (e.g., with an associated acoustic port) or a motion sensor (e.g., without an associated acoustic port).

In FIG. 2, each cantilever 30 has a piezoelectric structure formed in a piezoelectric layer 34, with the structure of each of the eight cantilevers 30 having an associated fixed end and an associated central end. The central ends of each cantilever 30 in FIG. 2 meet near a center, with edges of each cantilever 30 separated from adjacent cantilever by gaps between the cantilevers 30, as illustrated. During operation, the fixed ends remain stationary, and pressure from acoustic signals (e.g., from the acoustic port 24) incident on the cantilevers 30 causes a pressure differential, which causes the cantilevers 30 to deflect in and out (e.g., via a slight rotation around the fixed end). The deflection causes an electrical signal from the sensing electrodes 36/38 which creates the electrical signal that can be amplified by an analog front end and passed to processing circuitry as an audio signal. Such layers operate as acoustic layers converting acoustic energy into electrical signals during functional operation. The mechanical electrodes 36/40 provide mechanical structure in the central end of each cantilever 30. Overstress pressure as described in the context of FIG. 1E can cause excessive deflection, resulting in damage that can be avoided or reduced using overstress structures in accordance with aspects described herein.

Each cantilever 30 is positioned with sides adjacent to sides of another of the cantilevered beams separated by the gap between the cantilevers. The position of the eight cantilevers 30 with the gaps creates a symmetrical polygon shape bounded by the fixed bases around the outside of the symmetrical polygon (e.g., an octagon, with one exterior side for each of the cantilever 30). In other aspects, other shapes can be used. In other implementations, MEMS acoustic transducers can include cantilevered beams with different beam shapes for the same transducer, so long as the fixed exterior edges attached to the substrate form an enclosed transducer that separates air on one side (e.g., a pocket side) from air on another side (e.g., an acoustic port side similar to the acoustic port 24) using the cantilevered beams (e.g., the cantilevers 30) and gaps between the beams. The separation allows the pressure difference between the sides of the MEMS transducer to apply force to the beams and generate a signal that can be communicated to an analog front end and then to additional processing circuitry via the bond pads 48. Similarly, an electrical signal provided from transmit circuitry (e.g., such as Tx circuitry 52 of FIG. 1C) can cause the cantilevers 30 to deflect, generating an acoustic signal.

As illustrated in FIG. 2, the cantilevers 30 have an associated length, determined by the line segment from the tip of the central end that is perpendicular to the fixed extreme end of the fixed end. The line segment extends from the fixed end at the substrate to the tip of the central end. As described above, when sound vibrations are present at a surface of the deflection beams, the cantilevered beams will move due to the pressure (e.g., z direction movement in and out of the x-y plane illustrated in FIG. 2. The movement in and out of this plane is referred to herein as vertical deflection. The deflection at the fixed end will be less than the deflection at the central end, with the amount of deflection increasing along the distance of the line segment away from the substrate toward the tip of the central end. The electrodes that generate the electrical signals at the bond pads 48 in response to the acoustic vibrations on the cantilevers 30 can add rigidity to the cantilever 30, and so in some implementations, placement of the sensing electrodes 36/38 can be limited to a space approximately two-thirds of the line segment distance from the fixed attachment to the substrate at the fixed end towards the tip of the central end (e.g., limited to a fixed end). In some implementations, an electrode layer can cover a surface or x-y plane cross section of the entire illustrated fixed end of each of the cantilevered beams. In other implementations, smaller electrode shapes can be used in a portion of the fixed end of each of the cantilevers 30. In some aspects, the central end of each of the cantilevered beams does not include electrode layers. In some aspects, the electrode layers do not extend to the tip of the central end (e.g., the free movement end) of each cantilever 30 to avoid sensing free end movement in the deflection end (e.g., where the signal which is proportional to the stress in the cantilever) is lower.

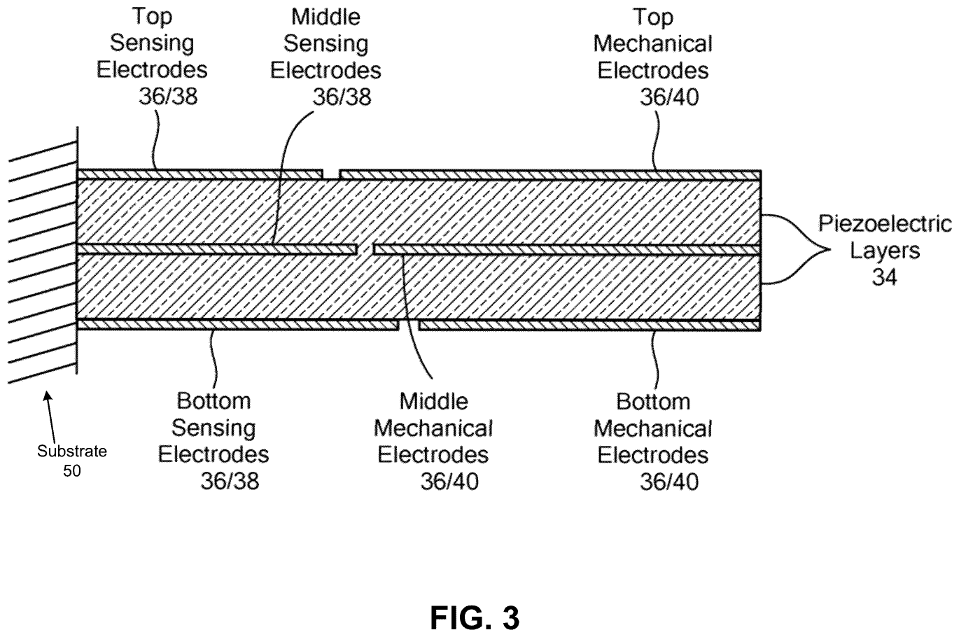

FIG. 3 illustrates a cross-sectional view of one portion of the MEMS microphone of FIG. 2 in accordance with aspects described herein. FIG. 3 shows an example cross-sectional view of one of those cantilevers 30. Other aspects of a piezoelectric MEMS acoustic transducer may use more or fewer cantilevers 30. Accordingly, as with other features, discussion of eight cantilevers 30 is for illustrative purposes only. These triangular cantilevers 30 are fixed to a substrate 50 (e.g., a silicon substrate) at their respective bases and are configured to freely move as part of acoustic layer operation in response to incoming/incident sound pressure (e.g., an acoustic wave). The intersection of the substrate 50 and the piezoelectric layers (e.g., as well as the electrodes at the substrate 50) are the fixed end of the cantilever(s) 30. Triangular cantilevers 30 can provide a benefit over rectangular cantilevers as the triangular cantilevers can be more simply configured to form a gap controlling geometry separating an acoustic port (e.g., the acoustic port 24) on one side of the cantilevers of the piezoelectric MEMS acoustic transducer from an air pocket on the other side of the cantilevers. Specifically, when the cantilevers 30 bend up or down due to either sound pressure or residual stress, the gaps between adjacent cantilevers 30 typically remain relatively small and uniform in the example symmetrical shapes with fixed ends using the triangular cantilevers 30.

The electrodes 36 are generally identified by reference number 36. However, the electrodes used to sense signals are referred to as “sensing electrodes” and are identified by reference number 38. These electrodes are electrically connected in series to achieve the desired capacitance and sensitivity values. In addition to the sensing electrodes 38, the rest of the cantilever 30 also may be covered by metal to maintain certain mechanical strength of the structure. However, these “mechanical electrodes 40” do not contribute to the electrical signal of the microphone output. As discussed above, some aspects can include cantilevers 30 without mechanical electrodes 40.

As described above, as a cantilever 30 bends or flexes around the fixed end as part of acoustic layer operation, and the sensing electrodes 36/38 generate an electrical signal. The electrical signal from an upward flex (e.g., relative to the illustrated positioning in FIG. 3, will be inverted compared with the signal of a downward flex. In some implementations, the signal from each cantilever 30 of a piezoelectric MEMS acoustic transducer can be connected to the same signal path so that the electrical signals from each cantilever 30 are combined (e.g., a shared bond pads 48). In other aspects, each cantilever 30 may have a separate signal path, allowing the signal from each cantilever 30 to be processed separately. In some aspects, groups of cantilevers 30 can be connected in different combinations. In some aspects, switching circuitry or groups of switches can be used to reconfigure the connections between multiple cantilevers 30 to provide different characteristics for different operating modes, such as transmit and receive modes.

In one aspect, adjacent cantilevers 30 can be connected to separate electrical paths, such that every other cantilever 30 has a shared path. The electrical connections in such a configuration can be flipped to create a differential signal. Such an aspect can operate such that when an acoustic signal incident on a piezoelectric MEMS acoustic transducer causes all the cantilevers 30 to flex upward, half of the cantilevers 30 create a positive signal, and half the cantilevers 30 create a negative signal. The two separate signals can then be connected to opposite inverting and non-inverting ends of an amplifier of an analog front end. Similarly, when the same acoustic vibration causes the cantilevers 30 to flex downward, the signals of the two groups will flip polarity, providing for a differential electrical signal from the piezoelectric MEMS acoustic transducer.

Alternatively, rather than alternating cantilevers 30 within a single piezoelectric MEMS transducer to create a differential signal, identical MEMS transducers can be placed across a shared acoustic port (e.g., the acoustic port 24), with the connections to the amplifier of an analog front-end reversed and coupled to different inverting and non-inverting inputs of a differential amplifier of the analog front-end to create the differential signal using multiple piezoelectric MEMS transducers.

The cantilever 30 can be fabricated by one or multiple layers of piezoelectric material sandwiched by top and bottom metal electrodes 36. FIG. 3 schematically shows an example of this structure. The piezoelectric layers 34 can be made by piezoelectric materials used in MEMS devices, such as one or more of aluminum nitride (AlN), aluminum scandium nitride (AlScN), zinc oxide (ZnO), and lead zirconate titanate (PZT). The electrodes 36 can be made by metal materials used in MEMS devices, such as one or more of molybdenum (Mo), platinum (Pi), nickel (Ni) and aluminum (Al). Alternatively, the electrodes 36 can be formed from a non-metal, such as doped polysilicon. These electrodes 36 can cover only a portion of the cantilever 30, e.g., from the base to about one third of the cantilever 30, as these areas generate electrical energy more efficiently within the piezoelectric layer 34 than the areas near the central end (e.g., the free movement end) of each cantilever 30. Specifically, high stress concentration in these areas near the base induced by the incoming sound pressure is converted into electrical signal by direct piezoelectric effect.

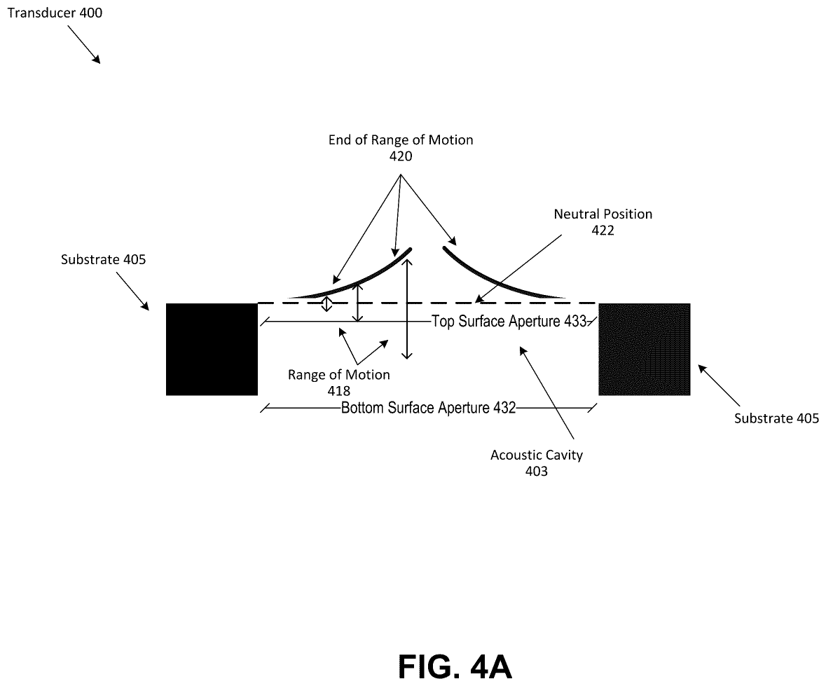

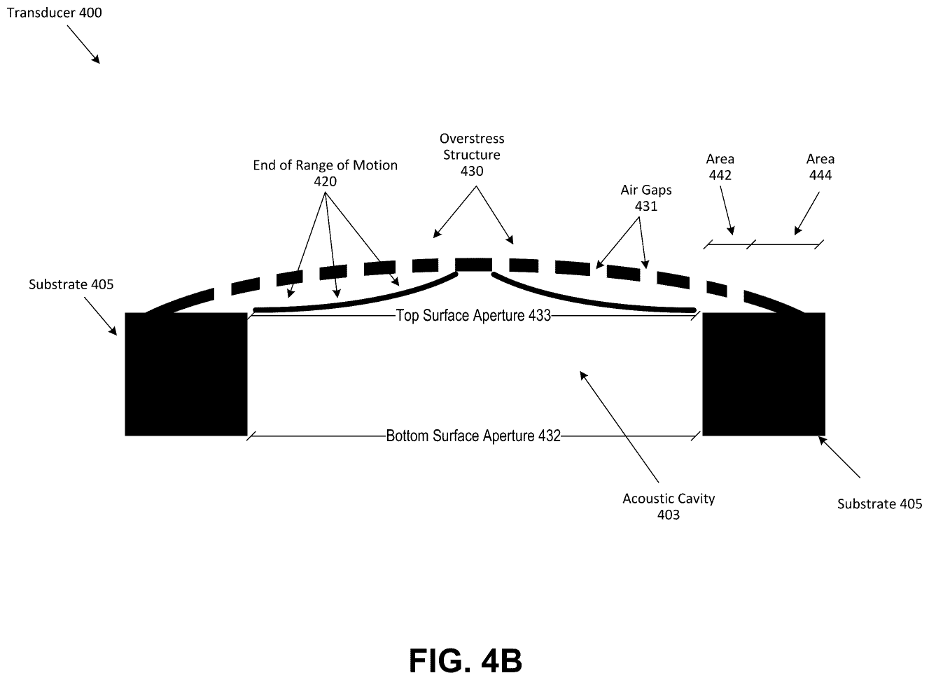

FIG. 4A illustrates aspects of a piezoelectric MEMS transducer 400 in accordance with aspects described herein. The transducer 400 can be a transducer similar to the transducer of FIG. 2, and can include beams as described in FIG. 3 implemented as an electroacoustic structure. The transducer 400 includes an electroacoustic structure including an acoustic layer having a range of motion 418 associated with pressure from an acoustic cavity 403 formed in a substrate 405. The acoustic cavity 403 is bounded by a top surface aperture 433, a bottom surface aperture 432, and walls of the substrate 405 on the sides of the acoustic cavity 403. In accordance with details above, the electroacoustic structure has a neutral position 422 when the pressure is at a steady state (e.g., equal on both sides). As sound vibrations propagate through the acoustic cavity 403, the electroacoustic structure will move within the range of motion 418 to generate electrical signals. When a pressure impulse (e.g., as described in FIG. 1E) passes through the acoustic cavity 403, the electroacoustic structure will deflect away from the bottom surface aperture 432 to an end 420 of the functional range of motion of an acoustic layer, and may exceed this range, resulting in damage or a break in the acoustic layer of the electroacoustic structure.

FIG. 4B illustrates aspects of the piezoelectric MEMS transducer 400 of FIG. 4A with overstress protection implemented via overstress structure 430 in accordance with aspects described herein. The overstress structure 430 is positioned to allow functional range of motion of the acoustic layer of the electroacoustic structure, such that vibrations can be detected, but to provide a physical block to stop the acoustic layer of the electroacoustic structure when it is at or beyond an end 420 of a functional range of motion. Depending on the design, when a high pressure pushes an acoustic layer of an electroacoustic structure to a point where the acoustic layer and/or elements of the electroacoustic structure approaches or exceeds an end of a functional range, the overstress structure 430 physically blocks movement of the acoustic layer and/or the electroacoustic structure. The positioning of the overstress structure can vary depending on performance targets of a device. For example, if transduction performance is a priority, the overstress structure 430 may be positioned outside the end 420 range of motion, so that an impact on noise and transduction performance is reduced. For improved overstress protection, the overstress structure 430 may be placed at or inside the end 420 of the functional range of motion, reducing transduction performance, but reducing the probability of overstress failure.

The electroacoustic structure can be connected to the substrate 405 at an area 442 near or adjacent to an edge of the top surface aperture so that the electroacoustic structure covers the top surface aperture 433. The overstress structure 430 can be supported by the substrate 405 or an edge of the electroacoustic structure in a second or outer area 444, so that the overstress structure surrounds both the top surface aperture 433 and the associated electroacoustic structure.

FIG. 4B illustrates a side view, which may be interpreted as a slice through the center of a transducer such as the transducer of FIG. 2. In such an implementation, the overstress structure 430 is a dome over the electroacoustic structure of the transducer 400. As detailed below, other structures can be used. The transducer 400 operates based on pressure differentials between different sides of the electroacoustic structure. The addition of the overstress structure 430 can result in a squeeze film effect, where the vibrations of the electroacoustic structure are damped as air squeezes around the overstress structure 430. In various implementations, air gaps 431 can be added to the overstress structure 430 to reduce this damping and configure transduction performance for a particular implementation.

The overstress structure 430 and similar structures described herein can be configured in various ways while limiting performance impact. The addition of a structure over an electroacoustic structure can impact the response of the electroacoustic structure through the “squeeze film damping effect”, where the added structure slows passage of air, damps (e.g., reduces the amplitude of) vibrations, and extends a settling time. In order to provide benefits and limit impacts on performance, the added structure for overstress protection is positioned far enough away from the electroacoustic structure that squeeze damping effects are limited. These effects are larger for structures near the center of an acoustic aperture, so the overstress structures can be positioned closer to the electroacoustic structures at supporting edges around the acoustic aperture. A lower mass is generally preferable to reduce impacts of added mass on a design, while having sufficient mass and stiffness to stop the movement of an electroacoustic structure.

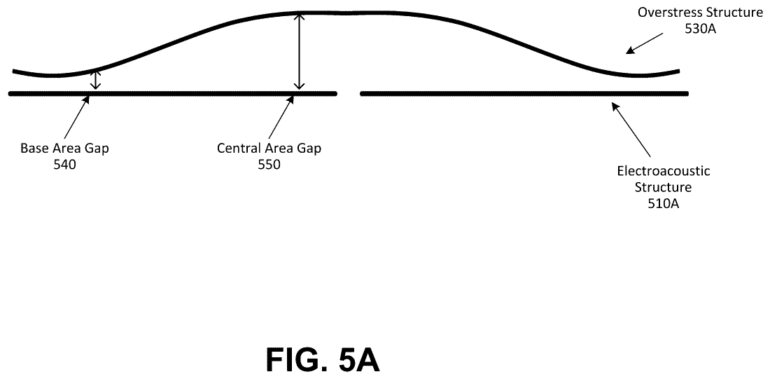

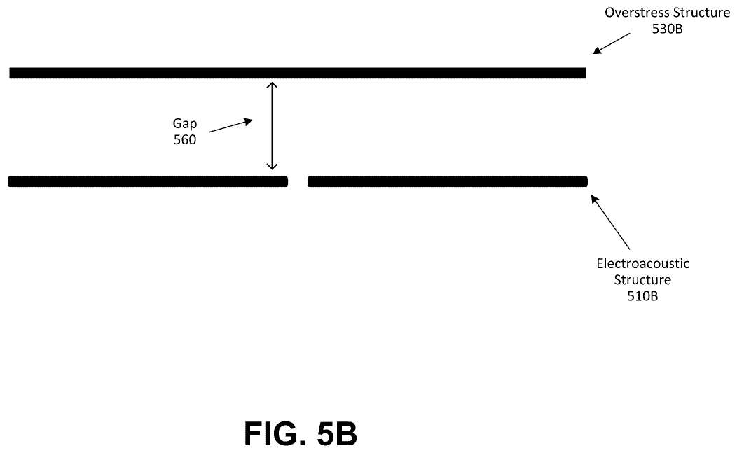

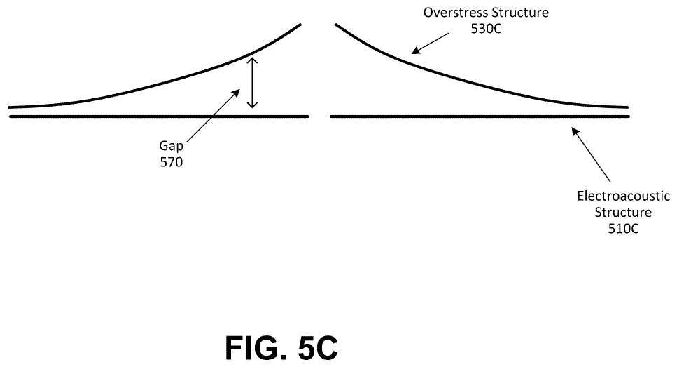

FIG. 5A illustrates aspects of an example overstress protection structure 530A positioned relative to a neutral position MEMS electroacoustic structure 510A in accordance with aspects described herein. FIG. 5A illustrates only the overstress structure 530A relative to the electroacoustic structure 510A, without showing the substrate used to support both structures. When a pressure pulse impacts the electroacoustic structure 510A, the greatest range of motion of the electroacoustic structure 510A is in a central area (e.g., nearer a center of a top surface aperture), while the greatest strain in the electroacoustic structure 510A is near a base where the electroacoustic structure attaches to a substrate. The dome configuration of overstress structure 530A illustrated in FIG. 5A, can provide a large range of motion in the center area, allowing a large central area gap 550 which allows functional movement of the electroacoustic structure 510A, while providing additional overstress support to the base of the electroacoustic structure with a smaller base area gap 540.

The shape of the overstress structure 530A can, in some implementations, be generated using a positive stress gradient with a tailored design in an Aluminum Nitride (AlScN), amorphous silicon (a-Si), a silicon nitride (SiN), or silicon oxide (SiO2) layer above the electroacoustic structure. Such a curved structure supported by a positive stress gradient may provide a greatest amount of overstress protection due to the ability to structure the impact of the electroacoustic structure 510A on the overstress structure 530A with the lowest impact on transduction performance. In various implementations, the base area gap 540 can be implemented from approximately 0 micrometers (um) (e.g., with the overstress structure 530A formed directly on the electroacoustic structure 510A in the base are) to approximately 5 um, and the central air gap can be selected based on the functional range of motion and performance characteristics of a particular design (e.g., from approximately 12-20 um in some aspects). In other aspects, the gap distance can be constant with a magnitude of approximately between 3 and 25 um.

FIG. 5B illustrates aspects of an example overstress protection structure 530B positioned relative to a neutral position MEMS electroacoustic structure 510B in accordance with aspects described herein. The overstress structure 530B is a flat stopper, which can provide an approximately constant gap. For a neutrally positioned electroacoustic structure, such an overstress structure 530B can impact performance, and provide less protection at the vulnerable base of the electroacoustic structure. In some aspects, such drawbacks can be reduced by designing an electroacoustic structure with downward angled cantilevers, or with an open center of the overstress structure 530B. In some implementations, aluminum nitride (AlN), aluminum scandium nitride (AlScN), molybdinum (Mo), silicon nitride (SiN), silicon oxide (SiO2), amorphous silicon (a Si), polycrystalline silicon, copper (Cu), nickel (Ni), or polymers can be used for the overstress structure 530B. In some aspects, a cost-effective implementation can be manufactured with a 3-5 um distance for the gap 560. In other aspects, other distances for the gap 560 can be selected based on the particular design of the system.

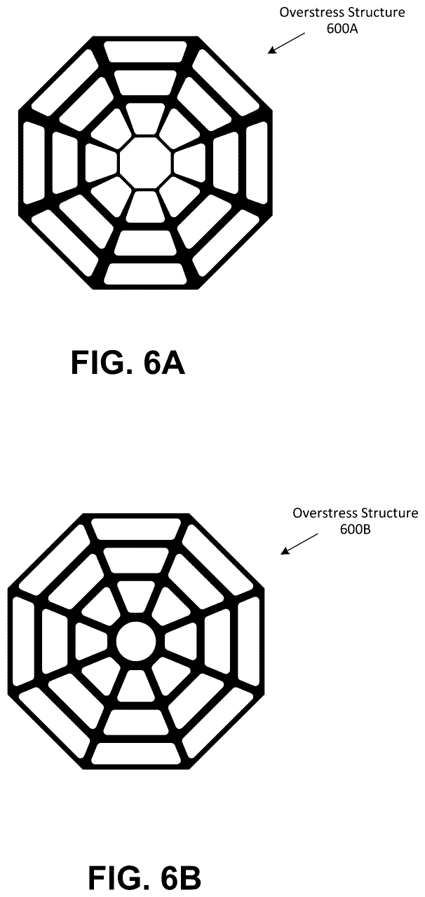

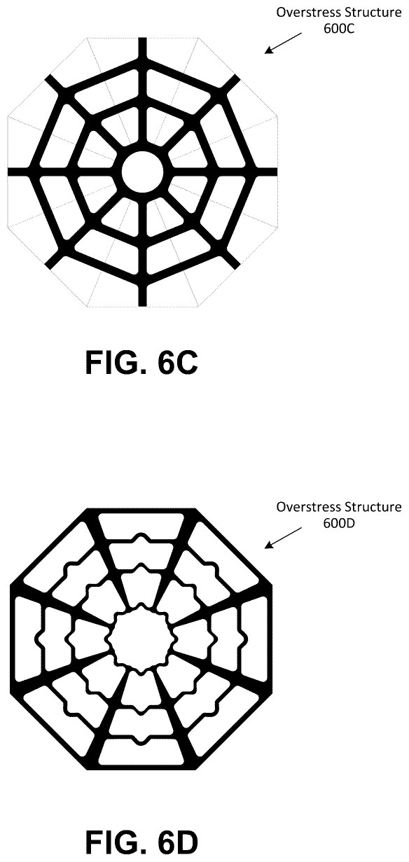

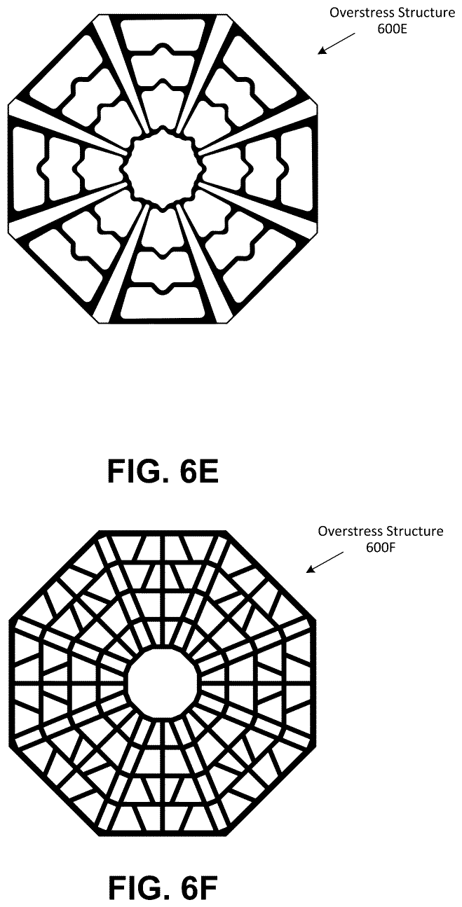

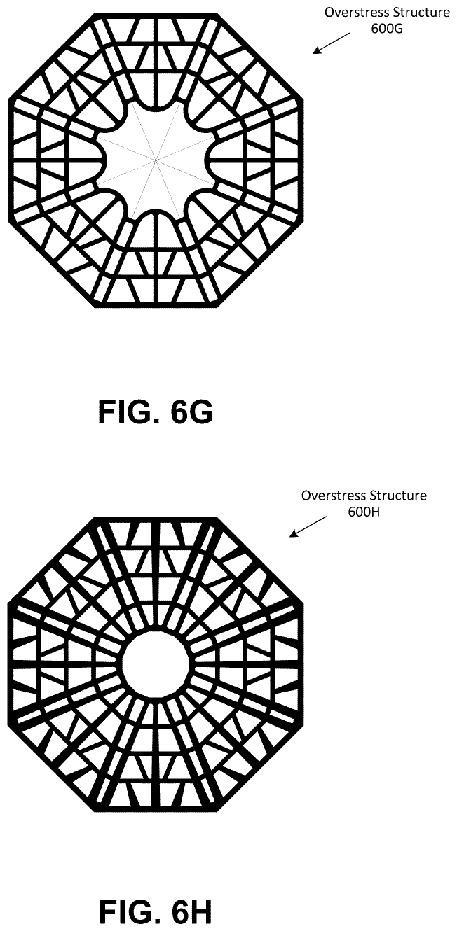

FIG. 5C illustrates aspects of an example overstress protection structure 530C positioned relative to a neutral position MEMS electroacoustic structure 510C in accordance with aspects described herein. The overstress structure 530C comprises cantilevered segments to form a stopper with an open central section where the cantilevered segments do not meet. The overstress structure 530C can provide an intermediate implementation, with greater cost than the overstress structure 530B and greater protection, but less protection than the overstress structure 530A depending on the particular design to provide the gap 570 limiting a range of motion of the electroacoustic structure 510C. Additional details of various implementations of the structures 530A-C are described below with respect to FIGS. 6A-H, 7, 8A-D, and 9 A-D.

FIGS. 6A-H illustrate top views of overstress protection structures 600A-H in accordance with aspects described herein. FIGS. 6A-H each illustrate a top-down view of an overstress structure implemented in a web configuration. Each of these example overstress structures illustrate aspects that can be modified or combined in different implementations to achieve varying levels of stiffness and structural integrity to achieve a desired level of overstress protection.

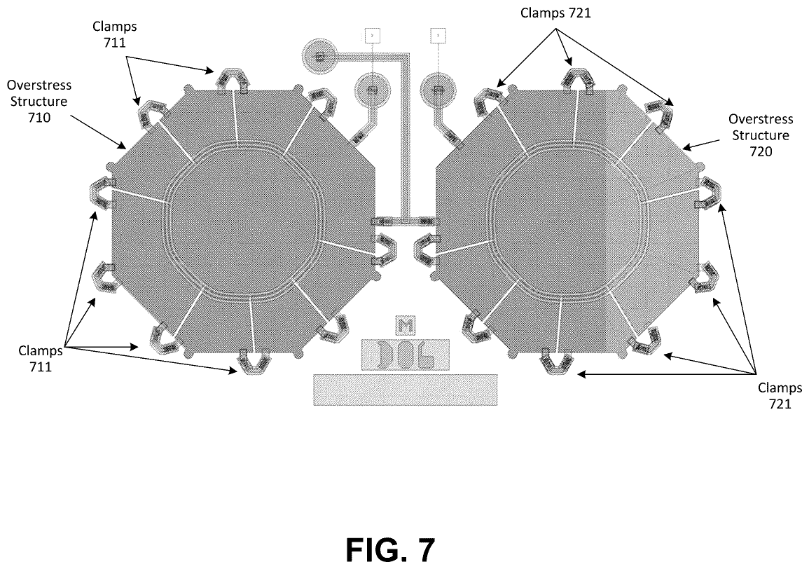

The examples of FIGS. 6A-H include radially or double clamped structures. While a full circular or polygonal membrane can be implemented, the web structures of FIGS. 6A-H provide details of possible implementations that provide options for stiffness and strength. Overstress structure 600A includes tapered cantilevered beams extending from a base to a central polygon, with tips of the beams near the central area of the aperture connected to the central polygon. One or more structures are added to connect adjacent cantilevered beams at various locations. In an example, the a plurality of structures connecting adjacent cantilevered beams may form a radial structure extending around all transducers. Other variations are also possible. For radial structure as in the overstress structure 600A, the central polygon is one of a plurality of radial structures positioned at different distances from the open central area inside the central polygon and leaving openings between each of the cantilevered beams. The additional radial structures are also polygons connecting each of the beams. The overstress structure 600B includes a similar structure, but with beams that are not tapered. The opposing beams in each of these implementations provide structure, with stiffness and strength based on the width of the beams and radial structures. The tapered beams of structure 600A provide additional strength near a base (e.g., where the overstress structure is connected to a supporting structure such as the substrate 5). The structure 600C does not include an outer radial structure at the contact base, so that a connection of the structure will occur at the base of the beams rather than throughout an entire radius surrounding the electroacoustic structure. Examples of clamp positions for such a structure are described in FIG. 7.

The overstress structure 600D includes interior radial structures with curved spring structures. Such curved spring structures, shown in the central radial structure as well as the additional radial structures between the central radial structure and the exterior (e.g., base or substrate connection) radial structure, allow tailoring of tangential effective width and stiffness, and can reduce the likelihood of damage as an electroacoustic structure impacts the overstress structure.

Overstress structures 600E, 600F, 600G, and 600H include various combinations of supports between radial structures, size of a central opening inside a central radial structure, doubled cantilevers connecting to the central radial structure, and tapering for various aspects of the associated overstress structure. Such elements as well as other elements described herein can be combined in different ways to achieve targeted stiffness, impact on squeeze effect damping, and impact of functional range of motion of an electroacoustic structure (e.g., an upper end of a functional range due to the range of motion being limited by the overstress structure). For example, in overstress structures 600E and 600F, the parallel cantilevers can be positioned over gaps between electroacoustic beams to reduce a squeeze effect, while the larger tapered beams of overstress structures 600A and 600C can be aligned with such gaps to increase the squeeze damping effect.

In various implementations, each of the overstress structures 600A through 600H can be implemented either as a curved structure with a profile similar to a profile of the overstress structure 530A, or as a flat structure with a profile similar to a profile of the overstress structure 530B. A curved profile can be created using a stress and/or strain gradient in the deposition process, or by creating a shape in a sacrificial layer on which the structure is deposited.

FIG. 7 illustrates a top view of clamped overstress protection structures 710, 720 in accordance with aspects described herein. In FIG. 7, the top view shows overstress structures 710 and 720 covering corresponding electroacoustic structures. As described herein, the overstress structures can be coupled to an area of a substrate surrounding an area of the substrate where the electroacoustic structures are supported. In the implementation of FIG. 7, clamps 711 attach the overstress structure 710 to the substrate, and clamps 721 attach the overstress structure 720 to the substrate. Just as with the variations above, the number and position of the clamps used to position and fix an overstress structure can be varied based on the protection criteria associated with a particular design.

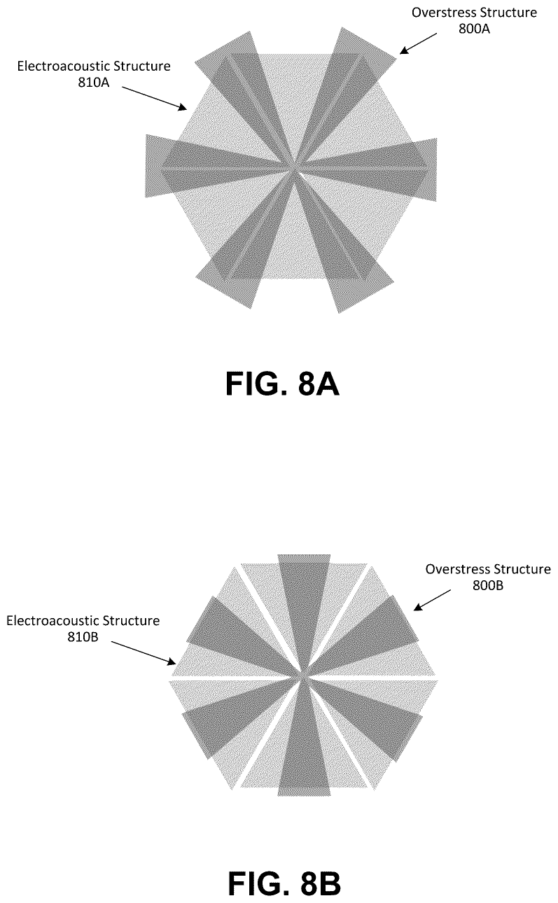

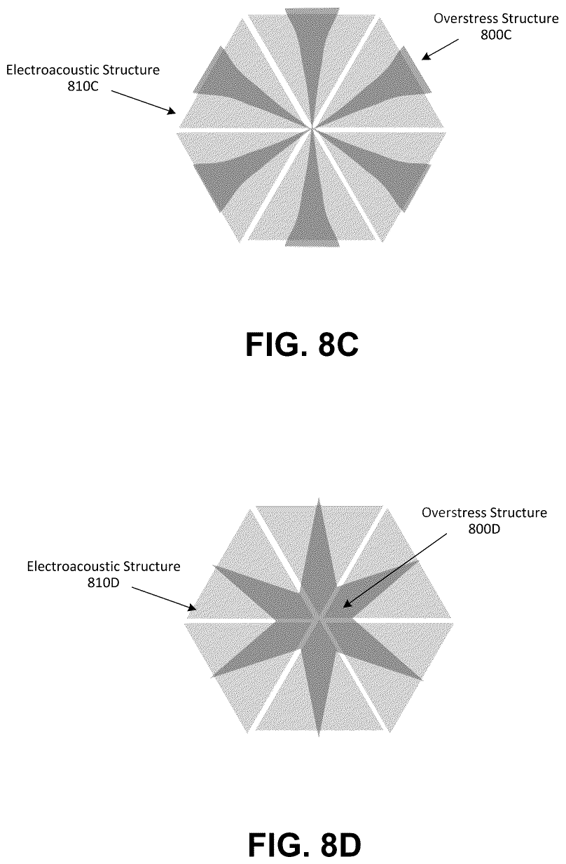

FIGS. 8A-D illustrate top views of cantilevered stoppers implemented as overstress protection structures in accordance with aspects described herein. In FIGS. 8A, similar cantilevered structures without added radial structures are illustrated from a top down perspective, with beams of an underlying electroacoustic structure also shown. In FIG. 8A, the linearly tapered beams of the overstress structure 800A are aligned with gaps between beams of the electroacoustic structure 810A. As described, such an alignment can be used to implement a valve type stopper blocking the gaps between MEMS diaphragm beams, and increasing the squeeze damping effect as a pressure impulse impacts a device. By contrast, in FIG. 8B, the same shape beams can be implemented leaving the gaps between MEMS diaphragm beams open, resulting in a pure mechanical stopper, where the physical contact between the electroacoustic structure 800B and the overstress structure 810B is used to prevent damage, rather than an additional reduction in the impact due to the squeeze effect from blocking the gap between MEMS diaphragm beams (e.g., and increasing the time for the two sides of the electroacoustic structure to stabilize with a same pressure.)

FIG. 8C illustrates an overstress structure 800C with non-linearly tapered beams, providing additional support in a base contact area with electroacoustic structure 810C, and FIG. 8D illustrates a reverse taper beam in overstress structure 800D, which increases the contact in a central aperture area with the electroacoustic structure 810D. Such a reverse taper can be implemented in some aspects to adjust a vertical stress gradient in position of the overstress structure 800D or in the impact connection between the electroacoustic structure 810D and the overstress structure 800D when contact is made between the structures during operation.

As described above, any of such structures can be modified in different implementations or integrated with other elements described herein. For example, in some implementations, the side profile may be implemented for overstress structures 800A-D with any profile from the overstress structures 530A-C of FIGS. 5A-C. Curved profiles similar to the profile of overstress structure 530A can be implemented using strain gradients or a shaped sacrificial layer, and a profile similar to the profile of overstress structure 530C of FIG. 5C can be implemented using an attachment structure or clamp with a beam sized to leave an optional opening between beams of an overstress structure.

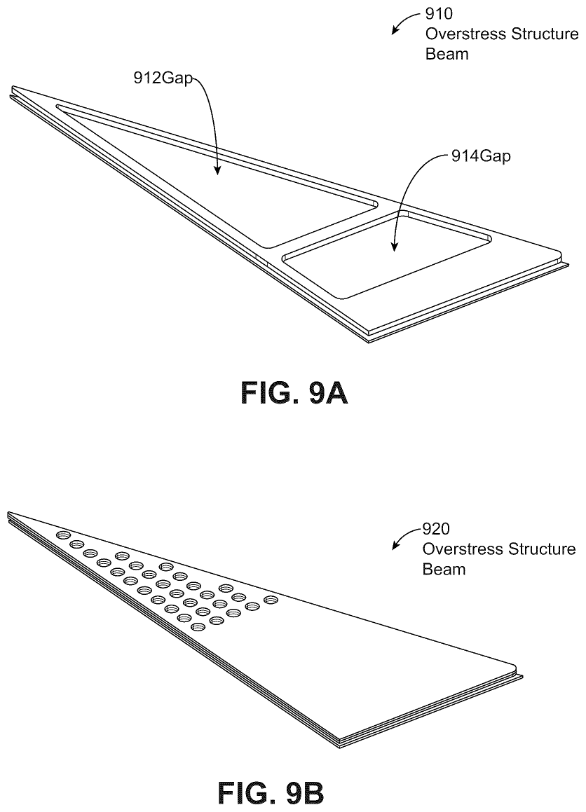

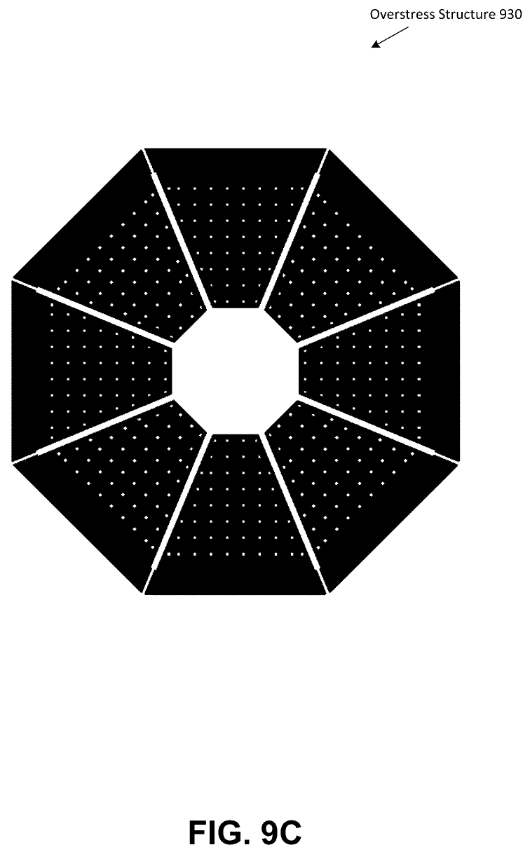

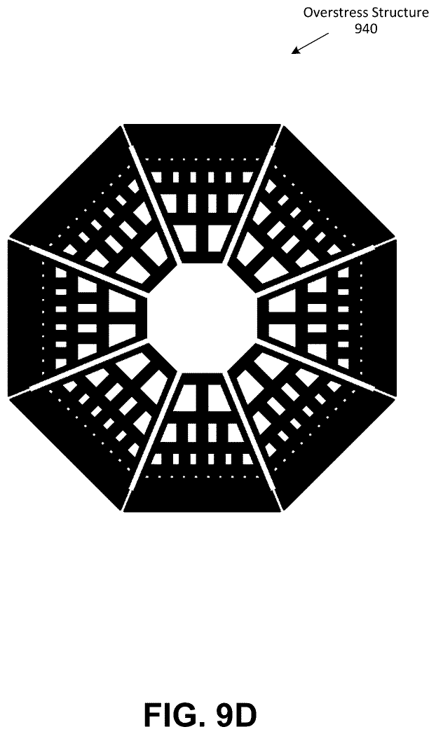

FIGS. 9A-D illustrate aspects of cantilevered beams 910, 920 implemented as overstress protection structures 930, 940 in accordance with aspects described herein. As described above for a piezoelectric MEMS microphone having independent beams, overstress protection structures can similarly be implemented with separate beams supported at an edge by a connection to a substrate (e.g., the substrate 5). FIG. 9A illustrates an overstress structure beam 910 having two large gaps 912 and 914 to allow air flow through the beam. FIG. 9B illustrates an overstress structure beam 920 having a same perimeter shape, but including holes in a central area to allow air flow through the holes. The number and size of the holes can be used to configure the squeeze damping effect impact on performance and overstress protection.

Such beams can be combined as illustrated in FIGS. 9C and 9D to provide overstress protection over an entire area of an electroacoustic MEMS structure, and can provide flexibility in protection and performance using elements as described herein. The overstress structure 930 includes beams designed to allow an open central area over a central portion of an aperture, while including holes to lessen a squeeze damping effect, and providing a solid base structure where the beams couple to a substrate. Overstress structure 940 of FIG. 9D provides a similar open central area, with larger open areas in the beam.

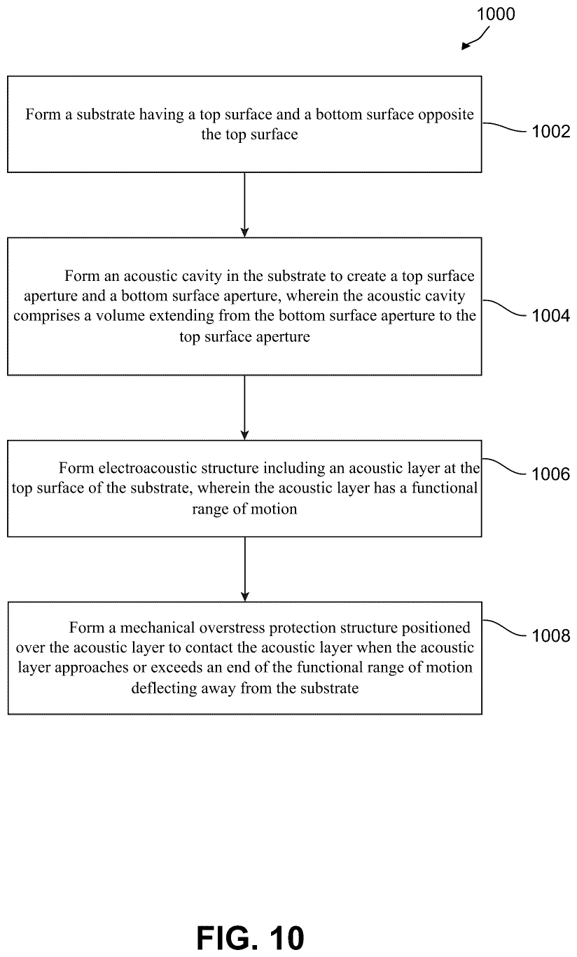

FIG. 10 illustrates a method 1000 of fabricating a MEMS device including a mechanical overstress protection structure in accordance with aspects described herein. The method 1000 as illustrated includes block 1002, which includes forming a substrate having a top surface and a bottom surface opposite the top surface. The method 1000 includes block 1004, which describes forming an acoustic cavity in the substrate to create a top surface aperture and a bottom surface aperture, wherein the acoustic cavity comprises a volume extending from the bottom surface aperture to the top surface aperture. The method 1000 includes block 1006, which describes forming electroacoustic structure including an acoustic layer at the top surface of the substrate, wherein the acoustic layer has a functional range of motion. The method 1000 includes block 1008, which describes forming a mechanical overstress protection structure positioned over the acoustic layer to contact the acoustic layer when the acoustic layer approaches or exceeds an end of the functional range of motion deflecting away from the substrate.

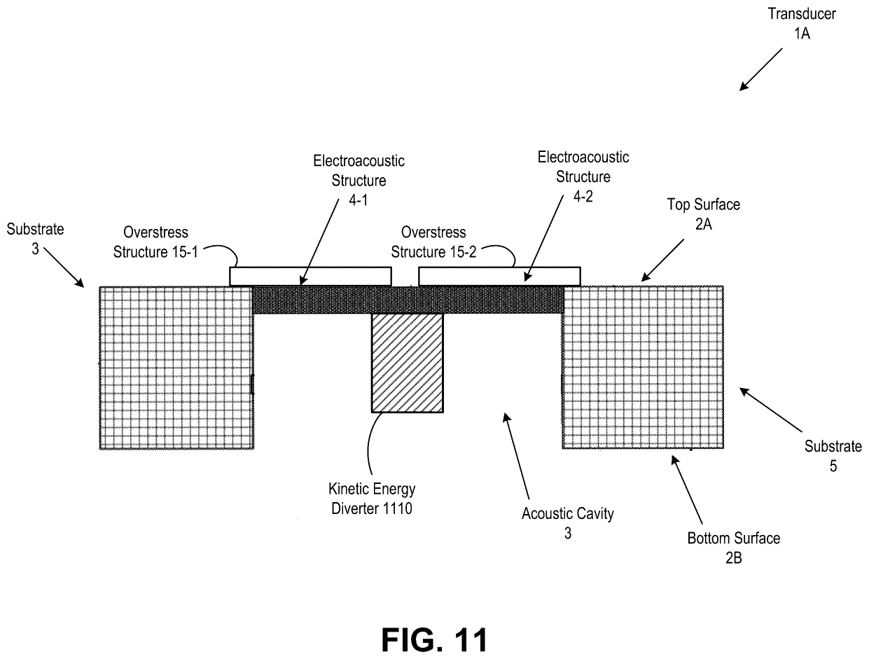

FIG. 11 illustrates a MEMS transducer 1A with overstress protection and kinetic energy diversion in accordance with aspects described herein. The MEMS transducer 1A is similar to the MEMS transducer 1 of FIG. 1A, but with two electroacoustic structures 4-1 and 4-2 configured in adjacent positions over an acoustic cavity 3 on shared substrate(s) 3 and 5 rather than a single electroacoustic structure as illustrated in FIG. 1A. The two electroacoustic structures 4-1 and 4-2 each have corresponding overstress structures 15-1 and 15-2.

In addition to the overstress structures 15-1 and 15-2 which protect the electroacoustic structures 4-1 and 4-2 which protect as the structures flex upward, the MEMS transducer 1A also includes a kinetic energy diverter 1110, which is disposed within the acoustic cavity 3. The energy diverter 1110 can be considered an energy attenuator that adds additional protection for the electroacoustic structures 4-1 and 4-2 by diverting kinetic energy in air as the air moves into the acoustic cavity 3 towards transducers of the electroacoustic structures 4-1 and 4-2. In some aspects, the energy diverter 1110 is contiguous with a top layer of the substrate(s) 3, 5 with the acoustic cavity 3 formed in a substrate around the kinetic energy diverter 1110. In other implementations, the kinetic energy diverter 1110 can be oriented horizontally instead of the illustrated vertical orientation, with the structure suspended from sidewalls of the acoustic cavity.

In operation, as a mass of air moves through the acoustic cavity 3 toward the electroacoustic structures 4-1 and 4-2, the air first encounters the kinetic energy diverter 1110. Some of the kinetic energy in the air is reflected or diverted, limiting the energy imparted into the electroacoustic structures 4-1 and 4-2, and decreasing the likelihood and/or magnitude of stress being exerted on the overstress structures 15-1 and 15-2. The overstress structures 15-1 and 15-2 can act together with the kinetic energy diverter 1110 to protect electroacoustic structures 4-1 and 4-2.

In various implementations, a single electroacoustic structure can be used with a kinetic energy diverter, or more than two electroacoustic structures can be present. A kinetic energy diverter of any size and/or shape that allows sufficient kinetic energy through to the electroacoustic structures for a given application (e.g., microphone, accelerometer, pressure sensor, etc.) can be used with any aspect described herein.

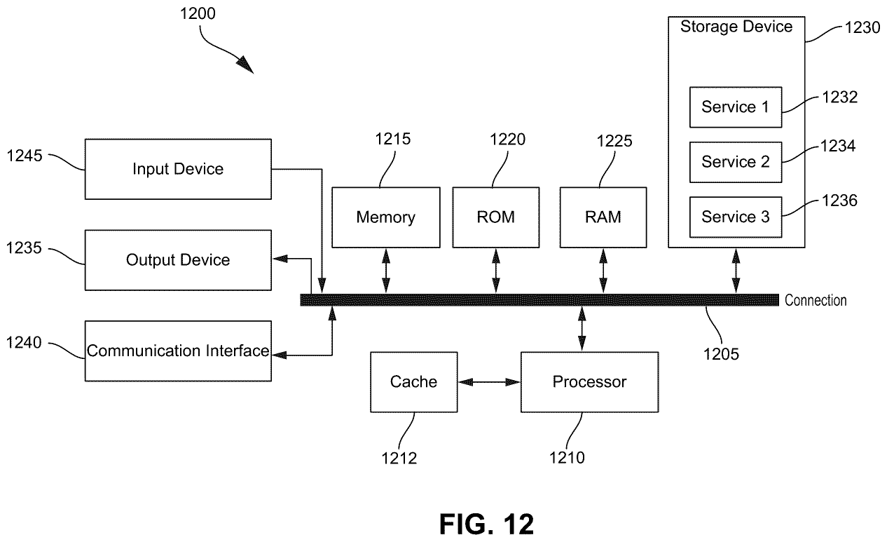

FIG. 12 is a diagram illustrating an example of a system for implementing certain aspects of the present technology. In particular, FIG. 12 illustrates an example of computing system 1200 which can include MEMS transducers or devices including MEMS transducers (e.g., implementations of the MEMS transducers 1, 1A, 1B) having overstress protection in accordance with aspects described herein. An acoustic transducer can be integrated, for example, with any computing device making up internal computing system, a remote computing system, a camera, or any component thereof in which the components of the system are in communication with each other using connection 1205. Connection 1205 may be a physical connection using a bus, or a direct connection into processor 1210, such as in a chipset architecture. Connection 1205 may also be a virtual connection, networked connection, or logical connection.

Example system 1200 includes at least one processing unit (CPU or processor) 1210 and connection 1205 that communicatively couples various system components including system memory 1215, such as read-only memory (ROM) 1220 and random access memory (RAM) 1225 to processor 1210. Computing system 1200 may include a cache 1212 of high-speed memory connected directly with, in close proximity to, or integrated as part of processor 1210.

Processor 1210 may include any general purpose processor and a hardware service or software service, such as services 1232, 1234, and 1236 stored in storage device 1230, configured to control processor 1210 as well as a special-purpose processor where software instructions are incorporated into the actual processor design. Processor 1210 may essentially be a completely self- contained computing system, containing multiple cores or processors, a bus, memory controller, cache, etc. A multi-core processor may be symmetric or asymmetric.

To enable user interaction, computing system 1200 includes an input device 1245, which may represent any number of input mechanisms, such as a microphone for speech or audio detection (e.g., piezoelectric MEMS transducer or a MEMS transducer system in accordance with aspects described above, etc.) along with other input devices 1245 such as a touch-sensitive screen for gesture or graphical input, keyboard, mouse, motion input, speech, etc. Computing system 1200 may also include output device 1235, which may be one or more of a number of output mechanisms. In some instances, multimodal systems may enable a user to provide multiple types of input/output to communicate with computing system 1200.

Computing system 1200 may include communications interface 1240, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 1240 may also include one or more Global Navigation Satellite System (GNSS) receivers or transducers that are used to determine a location of the computing system 1200 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1230 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1) cache, Level 2 (L2) cache, Level 3 (L3) cache, Level 4 (L4) cache, Level 5 (L5) cache, or other (L#) cache), resistive random-access memory (RRAM/ReRAM), phase change memory (PCM), spin transfer torque RAM (STT-RAM), another memory chip or cartridge, and/or a combination thereof.

The storage device 2230 may include software services, servers, services, etc., that when the code that defines such software is executed by the processor 2210, it causes the system to perform a function. In some embodiments, a hardware service that performs a particular function may include the software component stored in a computer-readable medium in connection with the necessary hardware components, such as processor 2210, connection 2205, output device 2235, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:

Aspect 1. A microelectromechanical system (MEMS) transducer, comprising: a substrate having a top surface, a bottom surface opposite the top surface, a bottom surface aperture, and a top surface aperture; an acoustic cavity comprising a volume extending from the bottom surface aperture to the top surface aperture; an electroacoustic structure formed at the top surface of the substrate, wherein the electroacoustic structure comprises an acoustic layer, and wherein the acoustic layer has a functional range of motion; and a mechanical overstress protection structure formed over the acoustic layer and positioned to contact the acoustic layer when the acoustic layer approaches or exceeds an end of the functional range of motion deflecting away from the substrate.

Aspect 2. The MEMS transducer of Aspect 1, wherein the electroacoustic structure comprises a capacitive MEMS microphone, and wherein the acoustic layer comprises an acoustic membrane of the capacitive MEMS microphone.

Aspect 3. The MEMS transducer of Any of Aspects 1 through 2, wherein the electroacoustic structure comprises a piezoelectric MEMS microphone, and wherein the acoustic layer comprises a plurality of cantilevered piezoelectric beams.

Aspect 4. The MEMS transducer of Any of Aspects 1 through 3, further comprising a kinetic energy diverter formed in the acoustic cavity.

Aspect 5. The MEMS transducer of Any of Aspects 1 through 4, wherein the electroacoustic structure is coupled to the substrate in an first area surrounding the top surface aperture; and wherein the mechanical overstress protection structure is coupled to the substrate in a second area surrounding the first area.

Aspect 6. The MEMS transducer of Aspect 5, wherein the mechanical overstress protection structure is a flat stopper positioned with a gap distance above a neutral position of the electroacoustic structure.

Aspect 7. The MEMS transducer of Aspect 6, wherein the gap distance is approximately constant and between 3 and 25 micrometers (um).

Aspect 8. The MEMS transducer of Aspect 6, wherein the mechanical overstress protection structure is fabricated from a material selected from aluminum nitride (AlN), aluminum scandium nitride (AlScN), molybdinum (Mo), silicon nitride (SiN), silicon oxide (SiO2), amorphous silicon (a-Si), polycrystalline silicon, copper (Cu), or nickel (Ni).

Aspect 9. The MEMS transducer of Aspect 6, wherein the mechanical overstress protection structure is fabricated with a multi-layer structure comprising two or more different materials.

Aspect 10. The MEMS transducer of any of Aspects 5 through 9, wherein the mechanical overstress protection structure comprises a plurality of cantilevered stoppers extending over the top surface aperture.

Aspect 11. The MEMS transducer of Aspect 10, wherein each cantilevered stopper comprises a linearly tapered stopper positioned over a corresponding gap between MEMS beams of the electroacoustic structure.

Aspect 12. The MEMS transducer of Aspect 10, wherein each cantilevered stopper comprises a non-linearly tapered stopper extending from the second area to a central area above the top surface aperture.

Aspect 13. The MEMS transducer of Aspect 12, wherein a first gap distance between the electroacoustic structure and the mechanical overstress protection structure is between approximately 0 micrometers (um) and 5 um above the first area, and wherein a second gap distance above the central area of the top surface aperture.

Aspect 14. The MEMS transducer of any of Aspects 5 through 9, wherein the mechanical overstress protection structure comprises a clamped structure configured as a circular membrane, a polygon, or a web.

Aspect 15. The MEMS transducer of Aspect 14, wherein the mechanical overstress protection structure comprises the web with a plurality of beams, wherein each beam is positioned with an opposite beam across the top surface aperture, and wherein the mechanical overstress protection structure further comprises a plurality of radial structures positioned at different distances from an open central area.

Aspect 16. The MEMS transducer of Aspect 15, wherein the plurality of radial structures comprise curved spring structures.

Aspect 17. The MEMS transducer of Aspect 15, further comprising a plurality of support beams coupled between the plurality of radial structures at different angles.

Aspect 18. The MEMS transducer of Aspect 15, wherein the plurality of beams are curved using a stress gradient in a deposition process to configure a changing gap distance from the first area to the open central area.

Aspect 19. A piezoelectric microelectromechanical system (MEMS) device, comprising: a substrate having a top surface, a bottom surface opposite the top surface, a bottom surface aperture, and a top surface aperture; an acoustic cavity comprising a volume extending from the bottom surface aperture to the top surface aperture; a plurality of cantilevered piezoelectric beams coupled to the substrate in a perimeter area around the acoustic cavity and extending into or over the acoustic cavity; a mechanical overstress protection structure formed over the plurality of piezoelectric beams and coupled to the substrate in a second area surrounding the perimeter area, wherein the mechanical overstress protection structure is positioned to contact one or more of the plurality of cantilevered piezoelectric beams as they approach or exceed an upper end of a functional range of motion.

Aspect 20. A method of fabricating a microelectromechanical system (MEMS) transducer, comprising: forming a substrate having a top surface and a bottom surface opposite the top surface; forming an acoustic cavity in the substrate to create a top surface aperture and a bottom surface aperture, wherein the acoustic cavity comprises a volume extending from the bottom surface aperture to the top surface aperture; forming electroacoustic structure including an acoustic layer at the top surface of the substrate, wherein the acoustic layer has a functional range of motion; and forming a mechanical overstress protection structure positioned over the acoustic layer to contact the acoustic layer when the acoustic layer approaches or exceeds an end of the functional range of motion deflecting away from the substrate.

Aspect 21. A device comprising: means for sensing pressure in accordance with any aspect described herein.

Aspect 22. A method comprising operations for sensing air pressure in accordance with any aspect described herein.

Aspect 23. A non-transitory computer readable storage medium comprising instructions that, when executed by control circuitry of a device, cause the device to perform operations for sensing pressure in accordance with any aspects described herein.

What is claimed is:

1. A microelectromechanical system (MEMS) transducer, comprising:
a substrate having a top surface, a bottom surface opposite the top surface, a bottom surface aperture, and a top surface aperture;
an acoustic cavity comprising a volume extending from the bottom surface aperture to the top surface aperture;
an electroacoustic structure formed at the top surface of the substrate, wherein the electroacoustic structure comprises an acoustic layer, and wherein the acoustic layer has a functional range of motion; and
a mechanical overstress protection structure formed over the acoustic layer and positioned to contact the acoustic layer when the acoustic layer approaches or exceeds an end of the functional range of motion deflecting away from the substrate.

2. The MEMS transducer of claim 1, wherein the electroacoustic structure comprises a capacitive MEMS microphone, and wherein the acoustic layer comprises an acoustic membrane of the capacitive MEMS microphone.

3. The MEMS transducer of claim 1, wherein the electroacoustic structure comprises a piezoelectric MEMS microphone, and wherein the acoustic layer comprises a plurality of cantilevered piezoelectric beams.

4. The MEMS transducer of claim 1, further comprising a kinetic energy diverter formed in the acoustic cavity.

5. The MEMS transducer of claim 1, wherein the electroacoustic structure is coupled to the substrate in an first area surrounding the top surface aperture; and
wherein the mechanical overstress protection structure is coupled to the substrate in a second area surrounding the first area.

6. The MEMS transducer of claim 5, wherein the mechanical overstress protection structure is a flat stopper positioned with a gap distance above a neutral position of the electroacoustic structure.

7. The MEMS transducer of claim 6, wherein the gap distance is approximately constant and between 3 and 25 micrometers (um).

8. The MEMS transducer of claim 6, wherein the mechanical overstress protection structure is fabricated from a material selected from aluminum nitride (AlN), aluminum scandium nitride (AlScN), molybdinum (Mo), silicon nitride (SiN), silicon oxide (SiO2), amorphous silicon (a-Si), polycrystalline silicon, copper (Cu), or nickel (Ni).

9. The MEMS transducer of claim 6, wherein the mechanical overstress protection structure is fabricated with a multi-layer structure comprising two or more different materials.

10. The MEMS transducer of claim 5, wherein the mechanical overstress protection structure comprises a plurality of cantilevered stoppers extending over the top surface aperture.

11. The MEMS transducer of claim 10, wherein each cantilevered stopper comprises a linearly tapered stopper positioned over a corresponding gap between MEMS beams of the electroacoustic structure.

12. The MEMS transducer of claim 10, wherein each cantilevered stopper comprises a non-linearly tapered stopper extending from the second area to a central area above the top surface aperture.

13. The MEMS transducer of claim 12, wherein a first gap distance between the electroacoustic structure and the mechanical overstress protection structure is between approximately 0 micrometers (um) and 5 um above the first area, and wherein a second gap distance above the central area of the top surface aperture.

14. The MEMS transducer of claim 5, wherein the mechanical overstress protection structure comprises a clamped structure configured as a circular membrane, a polygon, or a web.

15. The MEMS transducer of claim 14, wherein the mechanical overstress protection structure comprises the web with a plurality of beams, wherein each beam is positioned with an opposite beam across the top surface aperture, and wherein the mechanical overstress protection structure further comprises a plurality of radial structures positioned at different distances from an open central area.

16. The MEMS transducer of claim 15, wherein the plurality of radial structures comprise curved spring structures.

17. The MEMS transducer of claim 15, further comprising a plurality of support beams coupled between the plurality of radial structures at different angles.

18. The MEMS transducer of claim 15, wherein the plurality of beams are curved using a stress gradient in a deposition process to configure a changing gap distance from the first area to the open central area.

19. A piezoelectric microelectromechanical system (MEMS) device, comprising:
a substrate having a top surface, a bottom surface opposite the top surface, a bottom surface aperture, and a top surface aperture;
an acoustic cavity comprising a volume extending from the bottom surface aperture to the top surface aperture;
a plurality of cantilevered piezoelectric beams coupled to the substrate in a perimeter area around the acoustic cavity and extending into or over the acoustic cavity;
a mechanical overstress protection structure formed over the plurality of cantilevered piezoelectric beams and coupled to the substrate in a second area surrounding the perimeter area, wherein the mechanical overstress protection structure is positioned to contact one or more of the plurality of cantilevered piezoelectric beams as they approach or exceed an upper end of a functional range of motion.

20. A method of fabricating a microelectromechanical system (MEMS) transducer, comprising:
forming a substrate having a top surface and a bottom surface opposite the top surface;
forming an acoustic cavity in the substrate to create a top surface aperture and a bottom surface aperture, wherein the acoustic cavity comprises a volume extending from the bottom surface aperture to the top surface aperture;
forming electroacoustic structure including an acoustic layer at the top surface of the substrate, wherein the acoustic layer has a functional range of motion; and
forming a mechanical overstress protection structure positioned over the acoustic layer to contact the acoustic layer when the acoustic layer approaches or exceeds an end of the functional range of motion deflecting away from the substrate.
